(19) United States
(12) Patent Application Publication
(10) Pub. No.: US 2022/0200062 A1
(43) Pub. Date: Jun. 23, 2022

(54) POWER STORAGE MODULE

(71) Applicant: Prime Planet Energy & Solutions, Inc., Tokyo (JP)

(72) Inventors: Yasumasa KOJIMA, Kasai-shi (JP); Takashi INAMURA, Himeji-shi (JP); Takatoshi KAGEYAMA, Kakogawa-shi (JP)

(21) Appl. No.: 17/551,199

(22) Filed: Dec. 15, 2021

(30) Foreign Application Priority Data
Dec. 21, 2020 (JP) 2020-211175

(51) Int. Cl. H01M 10/42; H02J 7/00; H05K 1/18; H01G 4/38

(52) U.S. Cl. CPC H01M 10/425; H02J 7/0013; H05K 1/189; H05K 2201/10037; H01G 4/38; H05K 2201/10022; H05K 2201/10015; H05K 1/181

(57) ABSTRACT

A cover member is provided on a resin plate to cover a flexible printed circuit board. The resin plate is provided with an opening at a position at which a thermistor element and a power storage cell are in contact with each other. The flexible printed circuit board has an extension piece portion extending to above the opening of the resin plate, and a root portion adjacent to the extension piece portion and wider than the extension piece portion. The thermistor element is disposed on the extension piece portion. The cover member has a protuberance that protrudes toward the resin plate side and that presses and bends the extension piece portion so as to press the thermistor element toward the power storage cell. The root portion is fixed to the resin plate.

This nonprovisional application is based on Japanese Patent Application No. 2020-211175 filed on Dec. 21, 2020, with the Japan Patent Office, the entire contents of which are hereby incorporated by reference.

### BACKGROUND OF THE INVENTION

### Field of the Invention

The present technology relates to a power storage module.

### Description of the Background Art

Japanese Patent Laying-Open No. 2019-135687 is a prior art document that discloses a configuration of a power storage module. The power storage module described in Japanese Patent Laying-Open No. 2019-135687 includes a plurality of power storage cells, a flue duct, a flexible printed circuit board, and a cover. The plurality of power storage cells are connected to each other by bus bars. The flue duct covers the plurality of power storage cells and includes a protrusion portion that protrudes from a surface of the flue duct. The flexible printed circuit board includes: an engagement portion disposed on the surface of the flue duct and engaged with the protrusion portion; and a branch portion located adjacent to the engagement portion and connected to the bus bar. The cover is provided on the flue duct and has a pressing piece that can press the flexible printed circuit board. The flexible printed circuit board is pressed to the flue duct side by the pressing piece, and the position of the flexible printed circuit board is fixed along the flue duct with the protrusion portion being engaged with the engagement portion.

### SUMMARY OF THE INVENTION

A thermistor element may be used to detect a temperature of a power storage cell. In this case, precision in detection by the thermistor element may be deteriorated due to positional deviation of the thermistor element with respect to the power storage cell.

The present technology has been made to solve the above-described problem and has an object to provide a power storage module to improve precision in positioning a thermistor element with respect to a power storage cell.

A power storage module according to the present technology includes a stack, a resin plate, a flexible printed circuit board, a thermistor element, and a cover member. In the stack, a plurality of power storage cells are stacked. The resin plate is placed on the stack. The flexible printed circuit board is placed on the resin plate and has an electric circuit electrically connected to the plurality of power storage cells. The thermistor element is provided on the electric circuit and is in contact with one power storage cell of the plurality of power storage cells to detect a temperature of the power storage cell. The cover member is provided on the resin plate to cover the flexible printed circuit board. The resin plate is provided with an opening at a position at which the thermistor element and the power storage cell are in contact with each other. The flexible printed circuit board has an extension piece portion extending to above the opening of the resin plate, and a root portion adjacent to the extension piece portion and wider than the extension piece portion. The thermistor element is disposed on the extension piece portion. The cover member has a protuberance that protrudes toward the resin plate side and that presses and bends the extension piece portion so as to press the thermistor element toward the power storage cell. The root portion is fixed to the resin plate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing a basic configuration of a battery pack.

FIG. 2 is a diagram showing battery cells and end plates in the battery pack shown in FIG. 1.

FIG. 3 is a diagram showing a battery cell in the battery pack shown in FIG. 1.

FIG. 4 is a perspective view showing a state in which a wiring module is provided on the battery pack.

FIG. 5 is a schematic top view of the wiring module placed on the battery pack.

FIG. 6 is a perspective view showing the vicinity of a thermistor element.

FIG. 7 is a schematic top view of a cover member that covers the wiring module.

FIG. 8 is a cross sectional view of the surroundings of the thermistor element in the wiring module.

FIG. 9 is a cross sectional view showing the vicinity of a root portion in a state in which the cover member is attached to the wiring module.

FIG. 10 is a cross sectional view of the vicinity of a root portion according to a first modification.

FIG. 11 is a cross sectional view of the vicinity of a root portion according to a second modification.

### DESCRIPTION OF THE PREFERRED EMBODIMENTS

Hereinafter, embodiments of the present technology will be described. It should be noted that the same or corresponding portions are denoted by the same reference characters, and may not be described repeatedly.

It should be noted that in the embodiments described below, when reference is made to number, amount, and the like, the scope of the present technology is not necessarily limited to the number, amount, and the like unless otherwise stated particularly. Further, in the embodiments described below, each component is not necessarily essential to the present technology unless otherwise stated particularly.

It should be noted that in the present specification, the terms “comprise”, “include”, and “have” are open-end terms. That is, when a certain configuration is included, a configuration other than the foregoing configuration may or may not be included. Further, the present technology is not limited to one that necessarily exhibits all the functions and effects stated in the present embodiment.

In the present specification, the term “battery” is not limited to a lithium ion battery, and may include another battery such as a nickel-metal hydride battery. In the present specification, the term “electrode” may collectively represent a positive electrode and a negative electrode. Further, the term “electrode plate” may collectively represent a positive electrode plate and a negative electrode plate.

In the present specification, the “power storage cell” or the “power storage module” is not limited to a battery cell or a battery module, and may include a capacitor cell or a capacitor module.

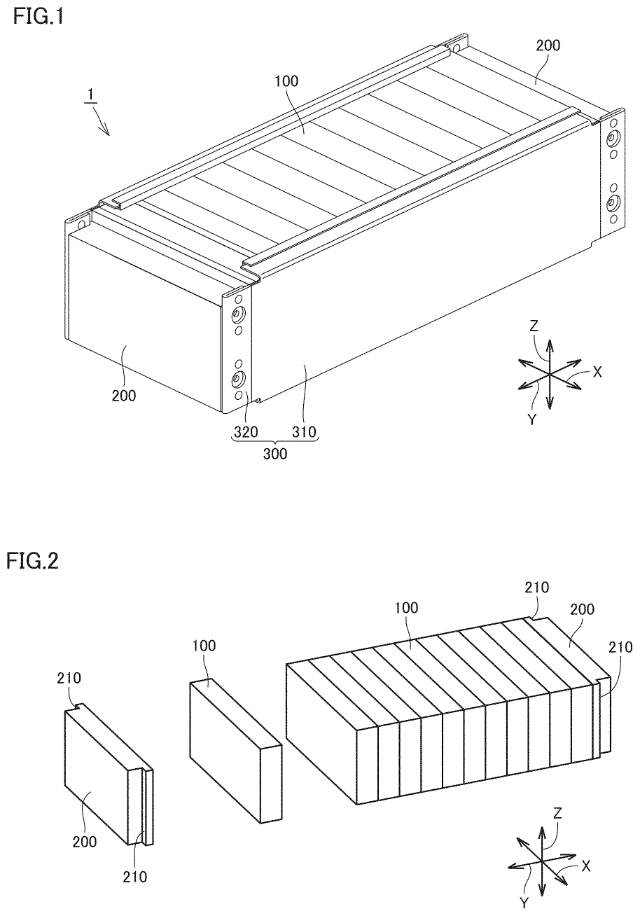

FIG. 1 is a diagram showing a basic configuration of a battery pack 1. FIG. 2 is a diagram showing battery cells 100 and end plates 200 included in battery pack 1.

As shown in FIGS. 1 and 2, battery pack 1, which serves as an exemplary “power storage module”, includes battery cells 100, end plates 200, and a restraint member 300.

The plurality of battery cells 100 are provided side by side in a Y axis direction (arrangement direction). Thus, a stack of battery cells 100 is formed. A separator (not shown) is interposed between the plurality of battery cells 100. The plurality of battery cells 100, which are sandwiched between two end plates 200, are pressed by end plates 200, and are therefore restrained between two end plates 200.

End plates 200 are disposed beside both ends of battery pack 1 in the Y axis direction. Each of end plates 200 is fixed to a base such as a case that accommodates battery pack 1. Stepped portions 210 are formed at both ends of end plate 200 in an X axis direction.

Restraint member 300 connects two end plates 200 to each other. Restraint member 300 is attached to stepped portions 210 formed on two end plates 200.

Restraint member 300 is engaged with end plates 200 with compression force in the Y axis direction being exerted to the stack of the plurality of battery cells 100 and end plates 200, and then the compression force is released, with the result that tensile force acts on restraint member 300 that connects two end plates 200 to each other. As a reaction thereto, restraint member 300 presses two end plates 200 in directions of bringing them closer to each other.

Restraint member 300 includes a first member 310 and a second member 320. First member 310 and second member 320 are coupled to each other by butt welding, for example. Tip surfaces formed by folding second member 320 are brought into abutment with stepped portions 210 of end plate 200 in the Y axis direction.

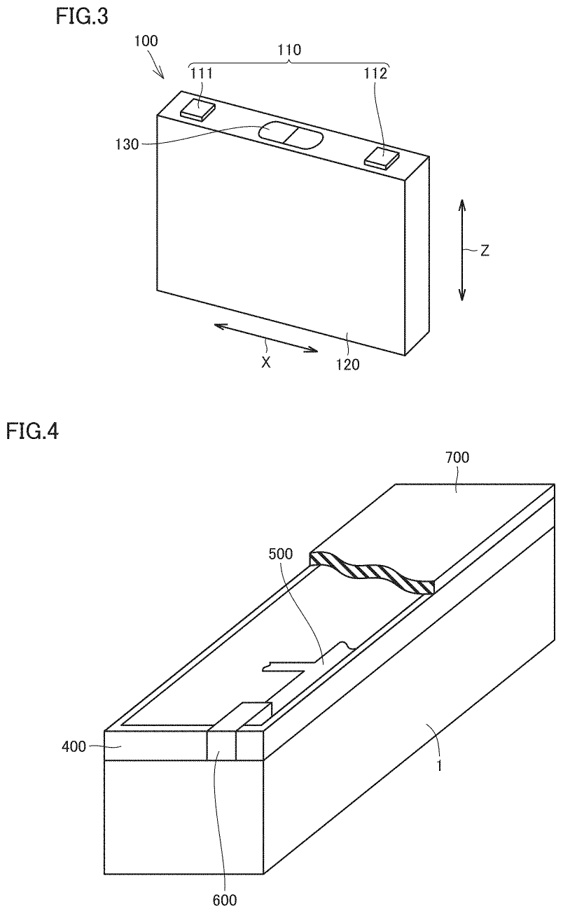

FIG. 3 is a diagram showing battery cell 100 in battery pack 1. As shown in FIG. 3, battery cell 100 includes electrode terminal 110, a housing 120, and a gas discharge valve 130.

Electrode terminal 110 includes a positive electrode terminal 111 and a negative electrode terminal 112. Electrode terminal 110 is formed on housing 120. Housing 120 is formed to have a substantially rectangular parallelepiped shape. An electrode assembly (not shown) and an electrolyte solution (not shown) are accommodated in housing 120. Gas discharge valve 130 is fractured when pressure inside housing 120 becomes equal to or more than a predetermined value. Thus, gas in housing 120 is discharged to the outside of housing 120.

FIG. 4 is a perspective view showing a state in which a wiring module is provided on battery pack 1. As shown in FIG. 4, a plate member 400 is placed on battery pack 1, and a flexible printed circuit board 500 is provided on plate member 400. Flexible printed circuit board 500 can be electrically connected to an external device via a connector 600. Cover member 700 is provided on plate member 400 so as to cover flexible printed circuit board 500.

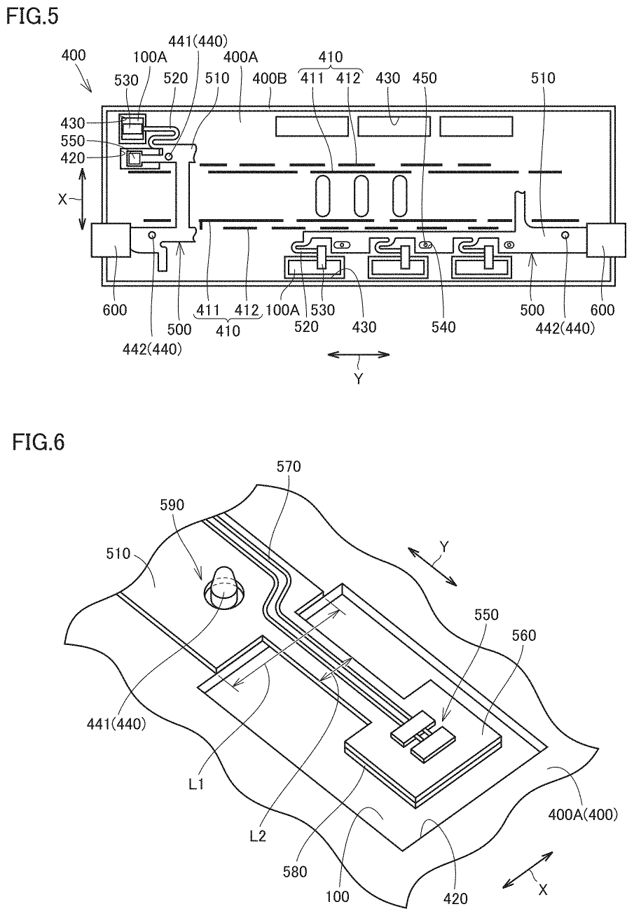

FIG. 5 is a schematic top view of the wiring module placed on battery pack 1. As shown in FIG. 5, the wiring module includes plate member 400, flexible printed circuit board 500, and connector 600.

Plate member 400 (bus bar plate) is a resin plate having insulation property and heat resistance. Plate member 400 has: a bottom surface portion 400A; and a side surface portion 400B formed to extend upward from bottom surface portion 400A in a Z axis direction. Plate member 400 is provided with wall portions 410, openings 420, 430, and protrusion portions 440, 450.

Each of wall portions 410 is formed to extend upward from bottom surface portion 400A of plate member 400 in the Z axis direction. Wall portion 410 includes: a first wall portion 411 formed on the center side in the X axis direction; and a second wall portion 412 provided on the outer side in the X axis direction in parallel with first wall portion 411. Each of first wall portion 411 and second wall portion 412 is formed to extend discontinuously in the Y axis direction.

Each of first wall portion 411 and second wall portion 412 can serve as a protection wall that prevents sparking generated in plate member 400 from being directly exposed to outside while securing a path for discharging, to the outside of the battery pack, the gas discharged from housing 120 of battery cell 100.

Opening 420 is located above a position between electrode terminal 110 and gas discharge valve 130 in battery cell 100 located at the end in the Y axis direction among the plurality of stacked battery cells 100. Openings 430 are located above electrode terminals 110 of the plurality of battery cells 100.

Protrusion portions 440 extend through flexible printed circuit board 500. Thus, flexible printed circuit board 500 is positioned. Protrusion portions 440 include a first protrusion portion 441 and a second protrusion portion 442. First protrusion portion 441 is used for positioning of a below-described thermistor element. Second protrusion portion 442 is used for positioning of connector 600.

The plurality of protrusion portions 450 are formed side by side in the Y axis direction. The plurality of protrusion portions 450 extend through flexible printed circuit board 500. The number of protrusion portions 450 can be appropriately changed.

Flexible printed circuit board 500 is a board in which an electric circuit is formed on a base member including a base film having an insulation property and a conductive metal foil. The base film is composed of, for example, polyimide or the like. The conductive metal foil is composed of, for example, a copper foil or the like. Flexible printed circuit board 500 has flexibility and has such a characteristic that the electric characteristics of flexible printed circuit board 500 are maintained even when deformed.

Flexible printed circuit board 500 is provided with a bus bar joining portion 530 electrically connected to electrode terminal 110. Bus bar joining portion 530 is joined to bus bar 100A that couples electrode terminals 110 of the plurality of battery cells 100. Thus, the electric circuit provided in flexible printed circuit board 500 and battery pack 1 are electrically connected to each other.

Connector 600 is fixed to flexible printed circuit board 500. The electric circuit in flexible printed circuit board 500 and an external electric device can be electrically connected to each other via connector 600.

Flexible printed circuit board 500 includes a main body portion 510 and displacement absorbing portions 520. Each of displacement absorbing portions 520 is formed by forming a portion of flexible printed circuit board 500 into a substantially U-shape so as to facilitate deformation. Displacement absorbing portion 520 is connected to bus bar joining portion 530. With displacement absorbing portion 520, displacements (in the X axis direction, the Y axis direction, and the Z axis direction) of bus bar joining portion 530 can be absorbed.

Flexible printed circuit board 500 is provided with a plurality of elongated holes 540 side by side in the Y axis direction. The number of elongated holes 540 can be appropriately changed. Each of the plurality of protrusion portions 450 is inserted into a corresponding one of the plurality of elongated holes 540. The lengths of elongated holes 540 in the Y axis direction are longer in the direction further away from connector 600. In this way, positioning can be readily performed when placing flexible printed circuit board 500 and connector 600 on plate member 400.

Thermistor element 550 is provided on the electric circuit of flexible printed circuit board 500. Thermistor element 550 is electrically connected to the electric circuit of flexible printed circuit board 500. Thermistor element 550 is disposed on one battery cell 100 located at the end in the Y axis direction among the plurality of battery cells 100 in battery pack 1. Thermistor element 550 is in contact with the above-described one battery cell 100 via opening 420 to detect the temperature of this battery cell 100. Thus, thermistor element 550 detects the temperature of battery cell 100 having the lowest temperature in battery pack 1. It should be noted that thermistor element 550 may detect the temperature of battery cell 100 having the highest temperature in battery pack 1, or a plurality of thermistor elements 550 may be used to detect the temperatures of a plurality of battery cells 100.

FIG. 6 is a perspective view showing the vicinity of the thermistor element. As shown in FIG. 6, opening 420 of plate member 400 is disposed at a position at which thermistor element 550 and battery cell 100 are in contact with each other.

Flexible printed circuit board 500 further includes an extension piece portion 560, a plate-like member 580, and a root portion 590. Extension piece portion 560 extends from main body portion 510 to above opening 420 of plate member 400. A portion of electric circuit 570 of flexible printed circuit board 500 is provided on extension piece portion 560 and is connected to thermistor element 550.

Thermistor element 550 is disposed on extension piece portion 560. In thermistor element 550, two elements are connected to electric circuit 570 in parallel. Thus, thermistor element 550 has a combined resistance value of resistance values of the two elements, so that variation in detected temperature is reduced as compared with a case where the temperature is detected using only one element. It should be noted that thermistor element 550 is not limited to the configuration in which the two elements are connected thereto in parallel, and may be constituted of one element. Further, the following configuration may be employed: one element (on the root portion 590 side) of the two elements is a capacitor element and the other element of the two elements is a thermistor element. According to this configuration, noise can be removed by the capacitor element, thereby detecting a precise temperature by thermistor element 550.

Plate-like member 580 is provided on the side of extension piece portion 560 opposite to the thermistor element 550 side. Plate-like member 580 is provided to improve heat conductivity between thermistor element 550 and battery cell 100 and to facilitate mounting of thermistor element 550 on flexible printed circuit board 500. Plate-like member 580 is composed of, for example, aluminum.

Root portion 590 is an end portion of main body portion 510 and is adjacent to extension piece portion 560. In root portion 590, first protrusion portion 441 extends through flexible printed circuit board 500.

Root portion 590 is wider than extension piece portion 560. Specifically, root portion 590 has a width size L1 in the X axis direction. Extension piece portion 560 has a width size L2 in the X axis direction. The ratio of width size L1 to width size L2 is, for example, more than or equal to 2 and less than or equal to 3. It should be noted that the ratio of width size L1 to width size L2 does not necessarily need to be more than or equal to 2 and less than or equal to 3 as long as extension piece portion 560 is readily bendable in the Z axis direction.

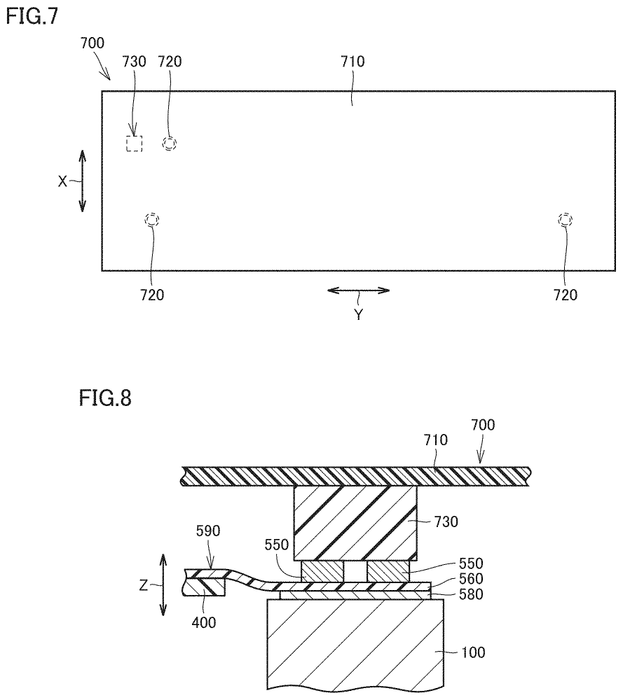

FIG. 7 is a schematic top view of cover member 700 (bus bar cover) that covers the wiring module shown in FIG. 5. Cover member 700 is provided on plate member 400 so as to cover flexible printed circuit board 500. As shown in FIG. 7, cover member 700 includes a main body 710, protrusions 720, and a protuberance 730.

Each of protrusions 720 protrudes toward flexible printed circuit board 500 on plate member 400. Protrusion 720 has a tubular shape.

Protuberance 730 protrudes toward the plate member 400 side. Protuberance 730 is provided at a position beside thermistor element 550 in the Z axis direction.

Protuberance 730 is adhered to main body 710. Protuberance 730 is, for example, a resin foam such as a sponge. It should be noted that protuberance 730 may be elastically deformable at least in the Z axis direction, and may be another resin elastic body such as a rubber or a resin spring, or may be a metal elastic body.

FIG. 8 is a cross sectional view of the surroundings of the thermistor element in the wiring module. As shown in FIG. 8, protuberance 730 is located between cover member 700 and thermistor element 550 in the Z axis direction, and presses and bends extension piece portion 560 so as to press thermistor element 550 toward battery cell 100. Specifically, protuberance 730 presses thermistor element 550 to thereby press extension piece portion 560 and plate-like member 580 in addition to thermistor element 550 toward battery cell 100. Thus, plate-like member 580 is brought into close contact with battery cell 100.

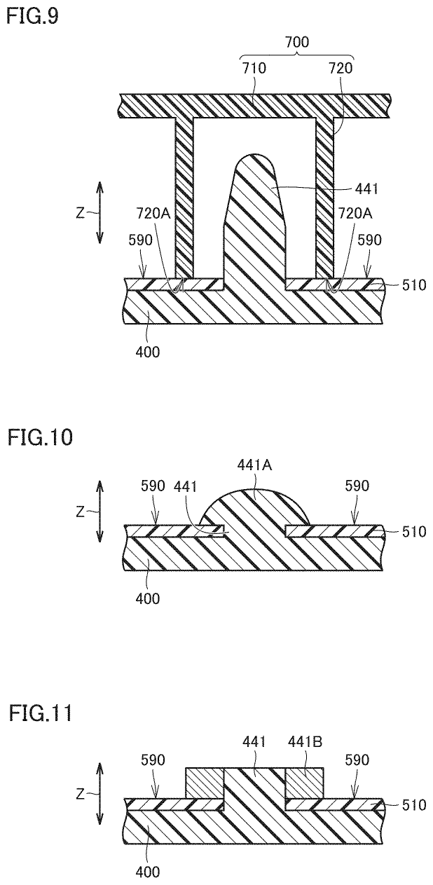

FIG. 9 is a cross sectional view showing the vicinity of the root portion in a state in which the cover member is attached to the wiring module. As shown in FIG. 9, protrusion 720 of cover member 700 is in abutment with flexible printed circuit board 500. Specifically, an abutment surface 720A of protrusion 720 is in abutment with flexible printed circuit board 500. Thus, root portion 590 is fixed to plate member 400 in the X axis direction, the Y axis direction, and the Z axis direction.

When protrusion 720 is brought into abutment with flexible printed circuit board 500, first protrusion portion 441 is accommodated inside protrusion 720. Since electric circuit 570 of flexible printed circuit board 500 is provided on the outer peripheral side with respect to abutment surface 720A of protrusion 720, electric circuit 570 and protrusion 720 do not interfere with each other.

In the power storage module according to the present embodiment, since thermistor element 550 is disposed on extension piece portion 560 extending from wide root portion 590 to above opening 420 and extension piece portion 560 is pressed and bent to press thermistor element 550 toward battery cell 100 with root portion 590 being fixed to plate member 400, the starting point of bending and the direction of bending of extension piece portion 560 can be maintained to be unchanged, thereby improving the precision in positioning thermistor element 550 with respect to battery cell 100.

In the power storage module according to the present embodiment, the precision in positioning thermistor element 550 with respect to battery cell 100 can be improved simply by fixing root portion 590 by the abutment of protrusion 720. It should be noted that a slight gap (less than or equal to 1 mm) may be provided between abutment surface 720A of protrusion 720 and flexible printed circuit board 500 as a structure for fixing root portion 590 to such an extent that precision in detection by thermistor element 550 is not decreased. Also with this structure, the positional deviation of root portion 590 in the X axis direction, the Y axis direction, and the Z axis direction can be suppressed, thereby improving the precision in positioning thermistor element 550 with respect to battery cell 100.

Hereinafter, a first modification of the embodiment of the present technology will be described. FIG. 10 is a cross sectional view of the vicinity of a root portion according to the first modification. As shown in FIG. 10, plate member 400 includes a first protrusion portion 441 that extends through flexible printed circuit board 500.

A swaged portion 441A is formed at the tip of first protrusion portion 441. Swaged portion 441A is formed by, for example, heat swaging. By swaging first protrusion portion 441, root portion 590 is fixed to plate member 400. In the present modification, protrusion 720 of cover member 700 is not necessarily required.

In the power storage module according to the first modification of the present embodiment, by fixing root portion 590 by swaging first protrusion portion 441, the precision in positioning thermistor element 550 with respect to battery cell 100 can be improved simply.

Hereinafter, a second modification of the embodiment of the present technology will be described. FIG. 11 is a cross sectional view of the vicinity of a root portion according to the second modification. As shown in FIG. 11, plate member 400 includes a first protrusion portion 441 that extends through flexible printed circuit board 500.

The outer peripheral portion of first protrusion portion 441 is fitted in a fixation member 441B having an annular shape. Fixation member 441B fixes root portion 590 to plate member 400. Specifically, fixation member 441B has an inner diameter smaller than the outer diameter of first protrusion portion 441, and root portion 590 is fixed to plate member 400 by press-fitting first protrusion portion 441 into fixation member 441B. Also in the present modification, protrusion 720 of cover member 700 is not necessarily required.

In the power storage module according to the second modification of the present embodiment, by fixing root portion 590 by fitting of first protrusion portion 441 in fixation member 441B, the precision in positioning thermistor element 550 with respect to battery cell 100 can be improved simply.

Although the embodiments of the present invention has been described and illustrated in detail, it is clearly understood that the same is by way of illustration and example only and is not to be taken by way of limitation, the scope of the present invention being interpreted by the terms of the appended claims.

What is claimed is:

1. A power storage module comprising:
a stack in which a plurality of power storage cells are stacked;
a resin plate placed on the stack;
a flexible printed circuit board placed on the resin plate and having an electric circuit electrically connected to the plurality of power storage cells;
a thermistor element provided on the electric circuit and in contact with one power storage cell of the plurality of power storage cells to detect a temperature of the power storage cell; and
a cover member provided on the resin plate to cover the flexible printed circuit board, wherein
the resin plate is provided with an opening at a position at which the thermistor element and the power storage cell are in contact with each other,
the flexible printed circuit board has an extension piece portion extending to above the opening of the resin plate, and a root portion adjacent to the extension piece portion and wider than the extension piece portion,
the thermistor element is disposed on the extension piece portion,
the cover member has a protuberance that protrudes toward the resin plate side and that presses and bends the extension piece portion so as to press the thermistor element toward the power storage cell, and
the root portion is fixed to the resin plate.

2. The power storage module according to claim 1, wherein
the cover member has a protrusion that protrudes toward the flexible printed circuit board on the resin plate, and
the root portion is fixed to the resin plate with the protrusion being in abutment with the flexible printed circuit board.

3. The power storage module according to claim 1, wherein
the resin plate includes a protrusion portion that extends through the flexible printed circuit board, and
the root portion is fixed to the resin plate with the protrusion portion being swaged.

4. The power storage module according to claim 2, wherein
the resin plate includes a protrusion portion that extends through the flexible printed circuit board, and
the root portion is fixed to the resin plate with the protrusion portion being swaged.

5. The power storage module according to claim 1, wherein the resin plate includes a protrusion portion that extends through the flexible printed circuit board,
the power storage module further comprising a fixation member provided at an outer peripheral portion of the protrusion portion to fix the root portion to the resin plate.

6. The power storage module according to claim 2, wherein the resin plate includes a protrusion portion that extends through the flexible printed circuit board,
the power storage module further comprising a fixation member provided at an outer peripheral portion of the protrusion portion to fix the root portion to the resin plate.
